(19) United States
(12) Patent Application Publication
(10) Pub. No.: US 2025/0270735 A1
(43) Pub. Date: Aug. 28, 2025

(54) LOW TEMPERATURE ATMOSPHERIC EPITAXIAL PROCESS

(71) Applicant: Applied Materials, Inc., Santa Clara, CA (US)

(72) Inventors: Susan PHAM, Santa Clara, CA (US); Balakrishnam R. JAMPANA, San Jose, CA (US); Naman GUPTA, Santa Clara, CA (US); Kazuyoshi KOBASHI, Santa Clara, CA (US); Kuan Chien SHEN, Sunnyvale, CA (US); Masato ISHII, Sunnyvale, CA (US); Chen-Yao CHAO, Santa Clara, CA (US); Ryan Sungbin HU, Santa Clara, CA (US)

(21) Appl. No.: 18/590,572

(22) Filed: Feb. 28, 2024

(51) Int. Cl. C30B 25/10; C30B 25/04; C30B 25/08; C30B 25/16; C30B 35/00

(52) U.S. Cl. CPC C30B 25/10; C30B 25/04; C30B 25/08; C30B 25/16; C30B 35/005

(57) ABSTRACT

A method of epitaxial deposition is disclosed. The method includes plasma pre-cleaning a substrate having openings with an aspect ratio of greater than 5:1. The plasma pre-cleaning is performed at pre-clean pressure of less than 5 Torr. The method also includes, after the plasma pre-cleaning, depositing a material in the openings using epitaxial deposition at a deposition pressure of about 700 Torr to about 800 Torr. In another embodiment, a method of gap filling using epitaxial deposition includes patterning a substrate with openings having an aspect ratio of 5:1. The method also includes plasma pre-cleaning the substrate, the plasma pre-cleaning being performed at a pre-clean pressure of about 1 Torr to about 5 Torr. The method also includes, after the plasma pre-cleaning, depositing a gap fill material in the openings using epitaxial deposition at a deposition pressure of about 700 Torr to about 800 Torr.

### BACKGROUND

### Field

Embodiments described herein generally relate to semiconductor device fabrication. More specifically, embodiments of the present disclosure relate to methods for epitaxial deposition.

### Description of the Related Art

In fabrication of an integrated circuit, prior to the epitaxial deposition process, a high temperature bake at a temperature of greater than 1100° C. is usually utilized to remove a native oxide. However, the high temperature bake may cause issues such as dopant diffusion and silicon migration. Further, the high temperature bake may damage the hard mask of a patterned substrate, which may prevent realization of selective atmospheric epitaxial processes.

In order to overcome these drawbacks, low pressure epitaxial deposition has been implemented. However, low pressure epitaxial deposition may have low throughput in a manufacturing environment due to the low growth rate of the deposited film.

Therefore, there is a need for more efficient methods of epitaxial deposition with dopant diffusion and silicon migration control.

### SUMMARY

Embodiments of the present disclosure provide a method of epitaxial deposition. The method includes plasma pre-cleaning a substrate having openings with an aspect ratio of greater than 5:1. The plasma pre-cleaning is performed at pre-clean pressure of less than 5 Torr. The method also includes, after the plasma pre-cleaning, depositing a material in the openings using epitaxial deposition at a deposition pressure of about 700 Torr to about 800 Torr.

Embodiments of the present disclosure provide a method of gap filling using epitaxial deposition. The method includes using epitaxial deposition includes patterning a substrate with openings having an aspect ratio of 5:1. The method also includes plasma pre-cleaning the substrate, the plasma pre-cleaning being performed at a pre-clean pressure of about 1 Torr to about 5 Torr. The method also includes, after the plasma pre-cleaning, depositing a gap fill material in the openings using epitaxial deposition at a deposition pressure of about 700 Torr to about 800 Torr.

Embodiments of the present disclosure provide a processing system. The processing system includes one or more processing chambers and a system controller configured to cause the processing system to perform, in the one or more processing chambers, a method. The method includes plasma pre-cleaning a substrate having openings with an aspect ratio of greater than 5:1. The plasma pre-cleaning is performed at a pre-clean pressure of about 1 Torr to about 5 Torr. The method also includes, after the plasma pre-cleaning, depositing a material in between the structures using epitaxial deposition at a deposition pressure of about 700 Torr to about 800 Torr.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a multi-chamber processing system, according to embodiments of the present disclosure.

FIG. 2 is a cross-sectional view of the pre-clean system from the multi-chamber processing system of FIG. 1, according to one embodiment.

FIG. 3 illustrates a method for low temperature epitaxial deposition, according to embodiments of the present disclosure.

FIG. 4 illustrates a method for low temperature gap filling using epitaxial deposition, according to embodiments of the present disclosure.

FIG. 5 is a cross-sectional view of the substrate having structures 507 disposed thereon, according to embodiments.

To facilitate understanding, identical reference numerals have been used, where possible, to designate identical elements that are common to the figures. It is contemplated that elements and features of one embodiment may be beneficially incorporated in other embodiments without further recitation. It is contemplated that elements disclosed in some embodiments may be beneficially utilized on other implementations without specific recitation.

### DETAILED DESCRIPTION

Embodiments described herein generally relate to semiconductor device fabrication. More specifically, embodiments of the present disclosure relate to methods for epitaxial deposition.

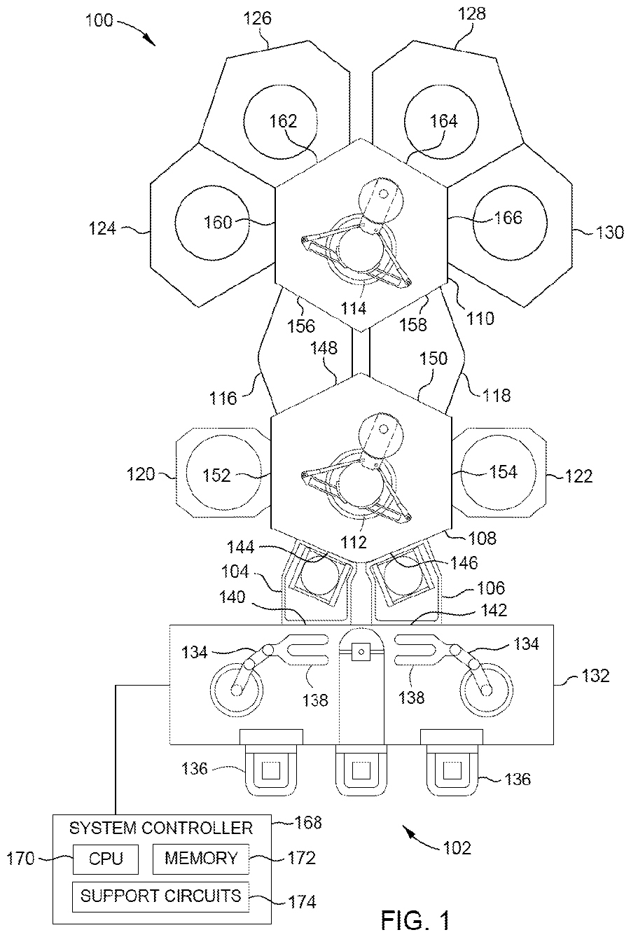

FIG. 1 is a schematic top view of a multi-chamber processing system 100, according to one or more embodiments of the present disclosure. The multi-chamber processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber processing system 100 can be processed in and transferred between the various chambers without exposing the substrates to an ambient environment exterior to the processing system 100. For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the multi-chamber processing system 100 may provide for an integrated solution for some processing of substrates.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system. The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 124, 126, 128, 130 can be capable of performing respective deposition processes.

A system controller 168 is coupled to the multi-chamber processing system 100 for controlling the multi-chamber processing system 100 or components thereof. For example, the system controller 168 may control the operation of the multi-chamber processing system 100 using a direct control of the chambers 104, 106, 108, 110, 116, 118, 120, 122, 124, 126, 128, 130 of the processing system multi-chamber 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

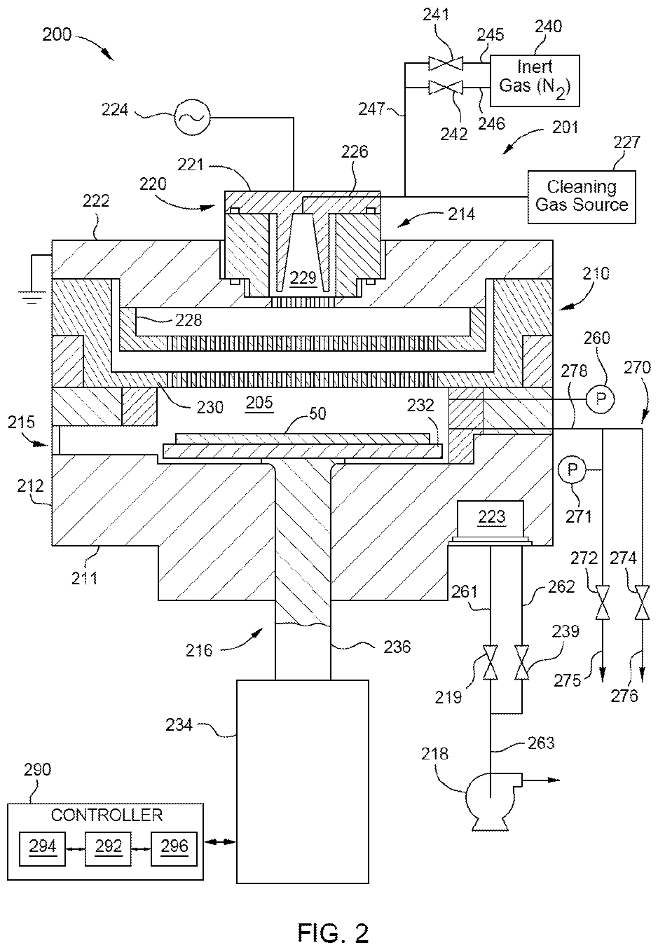

FIG. 2 is a cross-sectional view of the pre-clean system 200. The pre-clean system 200 may be one or more of the processing chambers 120, 122, 124, 126, 128, 130. The pre-clean system 200 includes a pre-clean chamber 201 (also referred to as a process chamber). The pre-clean chamber 201 includes a chamber body 210. The chamber body 210 includes a bottom 211, a lid assembly 214, and one or more chamber walls 212 connecting the bottom 211 with the lid assembly 214. The chamber body 210 can enclose an interior volume 205 of the pre-clean chamber 201.

The pre-clean chamber 201 further includes a substrate support assembly 216. The substrate support assembly 216 can include a substrate support 232, an actuator 234, and a shaft 236 connecting the actuator 234 with the substrate support 232. The substrate support 232 can be located in the interior volume 205 to support a substrate 50 during processing.

The chamber body 210 can further include a slit valve 215 to allow insertion and removal of a substrate 50 into and from the interior volume 205 of the pre-clean chamber 201. The pre-clean system 200 and multi-chamber processing system 100 can be configured to have a pressure in the interior volume 205 remain below a pressure in the transfer chamber 108 when the slit valve 215 is opened to prevent flow of gas and/or particles from the pre-clean chamber 201 to the transfer chamber 108 as described in further detail below.

The lid assembly 214 is disposed at an upper end of the chamber body 210. The lid assembly 214 can include a remote plasma source 220 for generating a plasma from cleaning gases provided to the remote plasma source 220. The cleaning gases can be provided from a cleaning gas source 227 through a gas inlet 226 of the pre-clean chamber 201. The cleaning gas source 227 can include a separate tank for each cleaning gas. In one embodiment, the cleaning gases from the cleaning gas source 227 can include one or more of hydrogen (H₂), nitrogen trifluoride (NF₃), and ammonia (NH₃). The remote plasma source 220 can include a first electrode 221 and a second electrode 222. The first electrode 221 can be spaced apart from the second electrode 222. The remote plasma source 220 can include a plasma-generating volume 229 positioned between the first electrode 221 and the second electrode 222.

The pre-clean system 200 can include a radio frequency (RF) power source 224. The RF power source 224 can be connected to the first electrode 221. The second electrode 222 can be connected to electrical ground to serve as a return path for the RF power when the plasma is generated in the volume 229. The RF power source 224 can be used to generate a plasma of the cleaning gases inside plasma-generating volume 229 when the cleaning gases are provided to the remote plasma source 220.

The lid assembly 214 can further include a blocker plate 228 and a showerhead 230 for distributing gas and/or plasma to the interior volume 205 of the pre-clean chamber 201. The blocker plate 228 can be positioned between the remote plasma source 220 and the showerhead 230. The blocker plate 228 can receive plasma and/or gas discharged from the remote plasma source 220. In some embodiments, one or more gases may be provided directly to the blocker plate 228 or showerhead 230 allowing the remote plasma source 220 to be bypassed.

The pre-clean system 200 can further include an inert gas source 240 connected to the pre-clean chamber 201. In one embodiment, the inert gas source 240 includes nitrogen, but in other inert gases (e.g., argon) may also be used. The inert gas can be used to pressurize the interior volume 205 of the pre-clean chamber 201 after a pre-clean process is performed on the substrate 50 and/or before a new substrate 50 is transferred into the pre-clean chamber 201. The pre-clean system 200 can include a pressure sensor 260 configured to measure a pressure of the interior volume 205 of the pre-clean chamber 201.

The inert gas source 240 can be connected to the gas inlet 226 of the process chamber through a first supply line 245 or a second supply line 246 of the pre-clean system 200. The first supply line 245 and the second supply line 246 can be connected to the gas inlet 226 through a common supply line 247. The first supply line 245 and the second supply line 246 can be arranged to form parallel (i.e., alternative) paths relative to each other, so that gas can be supplied to the pre-clean chamber 201 through one of the supply lines without going through the other supply line.

The first supply line 245 can include a first supply valve 241 that can be opened to connect the first supply line 245 with the common supply line 247. The second supply line 246 can include a second supply valve 242 that can be opened to connect the second supply line 246 with the common supply line 247.

The first supply line 245 can have a smaller internal diameter relative to the internal diameter of the second supply line 246. In some embodiments, the internal diameter of the first supply line 245 can be from about 5% to about 90%, such as from about 10% to about 50% of the internal diameter of the second supply line 246. The smaller diameter of the first supply line 245 can be used to slowly raise the pressure in the interior volume 205 from the vacuum pressures (e.g., 2-20 Torr, such as between about 3-5 Torr) used for the pre-clean process after a pre-clean process is performed on the substrate 50. On the other hand, the second supply line 246 can be used to quickly raise the pressure in the interior volume 205 back to atmospheric pressure or a pressure near atmospheric pressure after the pressure reaches a higher pressure (e.g., 300 Torr) from the gas provided from the smaller first supply line 245. Slowly raising the pressure after the pre-clean process can prevent the likelihood of damaging the substrate 50 from an abrupt pressure change, such as mechanical damage caused by a wobbling or otherwise unintentionally moving the substrate 50.

Using different supply lines with different internal diameters is one method of varying the rate at which gas is provided to the interior volume 205. In other embodiments, the slower pressure changes can be achieved, for example, with an analog control valve on a single supply line. In some of these other embodiments, a sensor, such as a flowmeter or pressure sensor can be used to control the analog control valve or other actuator (e.g., a variable-speed pump) in order to control the rate at which the pressure in the interior volume 205 increases when the inert gas is supplied to the interior volume 205, so that slower pressure changes in the interior volume 205 can be achieved.

The pre-clean system 200 can further include a vacuum pump 218 configured to exhaust gas from the pre-clean chamber 201 through an exhaust port 223 of the pre-clean chamber 201. The vacuum pump 218 can be connected to the exhaust port 223 through a first exhaust line 261 or a second exhaust line 262 of the pre-clean system 200. The first exhaust line 261 and the second exhaust line 262 can be arranged to form parallel (i.e., alternative) paths relative to each other, so that gas can be exhausted from the pre-clean chamber 201 through one of the exhaust lines without going through the other exhaust line. The first exhaust line 261 and the second exhaust line 262 can be connected to the exhaust port 223 through a common exhaust line 263. The first exhaust line 261 can include a first exhaust valve 219 that can be opened to fluidly couple the first exhaust line 261 with the common exhaust line 263. The second exhaust line 262 can include a second exhaust valve 239 that can be opened to fluidly couple the second exhaust line 262 with the common exhaust line 263.

The first exhaust line 261 can have a smaller internal diameter relative to the internal diameter of the second exhaust line 262. All references provided in this disclosure to internal diameters also apply to internal cross-sectional areas, for example if the component (e.g., a fluid conduit) has a non-circular cross-section. In some embodiments, the internal diameter of the first exhaust line 261 can be from about 5% to about 75%, such as from about 10% to about 50% of the internal diameter of the second exhaust line 262. The smaller diameter of the first exhaust line 261 can be used to smoothly and slowly lower the pressure in the interior volume 205 from atmospheric pressure or a pressure near atmospheric pressure (e.g., 700-800 Torr), to a lower pressure, such as from about 400-650 Torr, such as about 600 Torr. The pressure reduction can be performed, for example, after a substrate 50 is transferred into the pre-clean chamber 201 from the transfer chamber 108, which is maintained at atmospheric pressure or a pressure near atmospheric pressure. On the other hand, the second exhaust line 262 can be used to quickly lower the pressure in the interior volume 205 down to a pressure near the pressure used for the pre-clean plasma process, such as a pressure less than 50 Torr, such as about 100 mTorr to about 20 Torr, such as a pressure between about 300 mTorr and about 5 Torr). Slowly lowering the pressure after a substrate 50 is transferred into the pre-clean chamber 201 can prevent the likelihood of damaging the substrate 50 from an abrupt pressure change, such as mechanical damage caused by wobbling or otherwise unintentionally moving the substrate 50.

Using different exhaust lines with different internal diameters is one method of varying the rate at which gas and/or plasma is exhausted from the interior volume 205, so that slower pressure changes in the interior volume 205 can be achieved. In other embodiments, the slower pressure changes can be achieved, for example, with an analog control valve on a single exhaust line. In some of these other embodiments, a sensor, such as a flowmeter or pressure sensor can be used to control the analog control valve or other actuator (e.g., a variable-speed vacuum pump) in order to control the rate at which the pressure in the interior volume 205 decreases when the interior volume 205 is brought down to a vacuum pressure for performing the plasma pre-clean process.

As introduced above, the substrate support assembly 216 includes the substrate support 232, the actuator 234, and the shaft 236 connecting the actuator 234 with the substrate support 232. The shaft 236 can extend through a centrally-located opening formed in the bottom 211 of the chamber body 210. The actuator 234 may be flexibly sealed to the bottom 211 of the chamber body 210 by bellows (not shown) that prevent vacuum leakage from around the shaft 236. The actuator 234 allows the substrate support 232 to be moved vertically within the chamber body 210 between a process position and a lower transfer position. The transfer position can be slightly below the opening of the slit valve 215 formed through one of the one or more walls 212 of the chamber body 210.

Although not shown, in some embodiments, an RF and/or DC bias can be coupled to the substrate support 232 to assist with directing the cleaning plasma toward the substrate 50.

The pre-clean system 200 can further include an auxiliary exhaust assembly 270. The auxiliary exhaust assembly 270 can include a first auxiliary exhaust line 275, a second auxiliary exhaust line 276, and a common auxiliary exhaust line 278. The auxiliary exhaust assembly 270 can further include a vacuum pump or other device for creating a negative pressure in the auxiliary exhaust assembly 270 lines relative to the interior volume 205 of pre-clean chamber 201, so that gas is exhausted from the interior volume 205 through the auxiliary exhaust assembly 270 when the valves of the auxiliary exhaust assembly 270 are opened.

The common auxiliary exhaust line 278 can be connected to the interior volume 205 of the pre-clean chamber 201. The first auxiliary exhaust line 275 and the second auxiliary exhaust line 276 can be connected to the interior volume 205 of the pre-clean chamber 201 through the common auxiliary exhaust line 278. The first auxiliary exhaust line 275 can include a first auxiliary exhaust valve 272 that can be opened to connect the first auxiliary exhaust line 275 with the common auxiliary exhaust line 278. The second auxiliary exhaust line 276 can include a second auxiliary exhaust valve 274 that can be opened to connect the second auxiliary exhaust line 276 with the common auxiliary exhaust line 278.

The first auxiliary exhaust valve 272 can be opened when a high pressure condition occurs. The first auxiliary exhaust line 275 can include a pressure sensor 271 to measure a pressure inside the first auxiliary exhaust line 275. Upon measuring a pressure above a given threshold (e.g., 800 Torr), the first auxiliary exhaust valve 272 can be opened to relieve pressure inside the interior volume 205. Because the pre-clean chamber 201 is operated at a higher pressure than other pre-clean chambers that typically operate at vacuum pressures (e.g., less than 100 Torr) for the pre-clean process and substrate transfer, more components of the pre-clean chamber are fastened or otherwise secured to each other. For example, the components of the lid assembly 214 can be secured to other components in the lid assembly 214 and/or to the chamber walls 212. Some of these components in the lid assembly are generally unfastened for pre-clean chambers that operate at vacuum pressures for the pre-clean process and substrate transfer to and from the pre-clean chamber. The additional fastening of components in the pre-clean chamber 201 can help prevent movement of any of the components during the pressure changes that occur for each substrate pre-clean and transfer as described in further detail below. Securing these components though can create a safety issue as the previously unsecured components could move to relieve a high pressure situation. In the pre-clean chamber 201, the first auxiliary exhaust valve 272 can open to relieve a high pressure condition when measured by the pressure sensor 271 and prevent an unsafe high-pressure condition from occurring.

The second auxiliary exhaust valve 274 can be opened when the slit valve 215 is opened, which allows gas to flow from the interior volume 205 and out the auxiliary exhaust assembly 270. The interior volume 205 of the pre-clean chamber 201 is generally considered to be less clean than the interior volume of the transfer chamber 108. Thus, gas should not flow from the interior volume 205 of the pre-clean chamber 201 to the interior volume of the transfer chamber 108. Opening the second auxiliary exhaust valve 274 when the slit valve 215 opens reduces the pressure in the interior volume 205 relative to the pressure in the interior volume of the transfer chamber 108 and gas flows from the interior volume of the transfer chamber 108 through the interior volume 205 of the pre-clean chamber 201 and out through the auxiliary exhaust assembly 270.

The pre-clean system 200 can also include a controller 290 for controlling processes within the pre-clean system 200 (FIG. 2) and other portions of the processing system 100 (FIG. 1). The controller 290 can be any type of controller used in an industrial setting, such as a programmable logic controller (PLC). The controller 290 includes a processor 292, a memory 294, and input/output (I/O) circuits 296. The controller 290 can further include one or more of the following components (not shown), such as one or more power supplies, clocks, communication components (e.g., network interface card), and user interfaces typically found in controllers for semiconductor equipment.

The memory 294 can include non-transitory memory. The non-transitory memory can be used to store the programs and settings described below. The memory 294 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

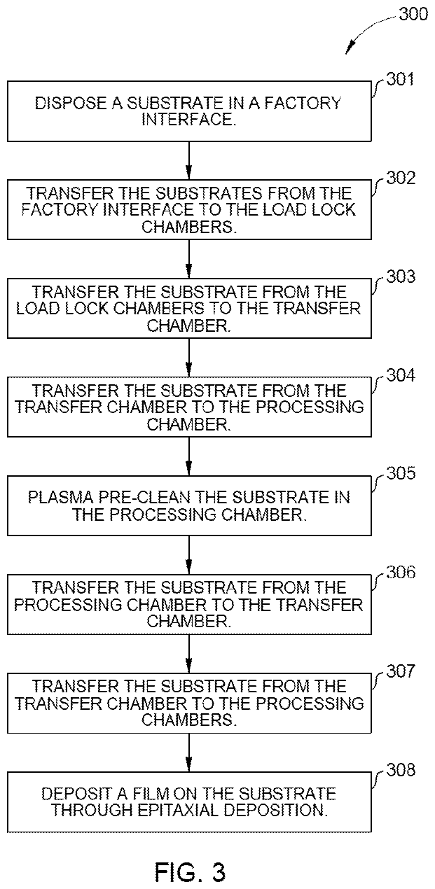

The processor 292 is configured to execute various programs stored in the memory 294, such as a program configured to execute the method 1000 described below in reference to FIG. 3. During execution of these programs, the controller 290 can communicate to I/O devices (e.g., sensors and actuators) through the I/O circuits 296. For example, during execution of these programs and communication through the I/O circuits, the controller 290 can control outputs (e.g., open and close valves) and receive information from feedback devices (e.g., feedback on the open/close state of valves), sensors, and other instrumentation in the pre-clean system 200 and other portions of the multi-chamber processing system 100.

The memory 294 can further include various operational settings used to control the pre-clean system 200 and other portions of the multi-chamber processing system 100. For example, the settings can include pressure settings for when a transition between slowly changing and more quickly changing the pressure in the interior volume 205 is made in the method 1000 as described below in reference to FIG. 3 among various other settings.

FIG. 3 is a method 300 for low temperature epitaxial deposition. At operation 301, a substrate is disposed in the factory interface 102. The factory interface 102 includes a docking station 132 and factory interface robots 134 to facilitate transfer of substrates. The docking station 132 is adapted to accept one or more front opening unified pods (FOUPs) 136.

At operations 302, the substrates are transferred from the factory interface 102 to the load lock chambers 104, 106. In some examples, each factory interface robot 134 generally includes a blade 138 disposed on one end of a respective factory interface robot 134 adapted to transfer the substrates from the factory interface 102 to the load lock chambers 104, 106. The load lock chambers 104, 106 have respective ports 140, 142 coupled to the factory interface 102 and respective ports 144, 146 coupled to a transfer chamber 108.

At operation 303, the substrate is transferred from the load lock chambers 104, 106 to the transfer chamber 108. The transfer chamber 108 has respective ports 148, 150 coupled to the holding chambers 116, 118 and respective ports 152, 154 coupled to processing chambers 120, 122.

At operation 304, the substrate is transferred from the transfer chamber 108 to the processing chambers 120, 122. The transfer chamber 108 has a pressure of about 700 Torr to about 800 Torr, such as about 760 Torr.

At operation 305, the substrate is plasma pre-cleaned in the processing chambers 120, 122. The pre-clean process includes removing a native-oxide from the substrate. The plasma pre-clean is conducted at a temperature of about 100° C. to about 300° C., such as about 150° C. to about 250° C., such as about 200° C. The plasma pre-clean is conducted at a pressure of about 1 Torr to about 5 Torr, such as about 3 Torr. The plasma pre-clean is conducted for a time of about 15 second to about 45 second, such as about 30 seconds.

At operation 306, the substrate is transferred from the processing chambers 120, 122 to the transfer chamber 110. The substrate is transferred to the transfer chamber 110 via the holding chambers 116, 118. The transfer chamber 110 has respective ports 156, 158 coupled to the holding chambers 116, 118 and respective ports 160, 162, 164, 166 coupled to processing chambers 124, 126, 128, 130.

At operation 307, the substrate is transferred from the transfer chamber to the processing chambers 124, 126, 128, 130. The transfer chamber 108 has a pressure of about 700 Torr to about 800 Torr, such as about 760 Torr.

At operation 308, a film is deposited on the substrate through epitaxial deposition. In some embodiments, the epitaxial deposition is a gap fill deposition, wherein the film (e.g., the deposition material) is deposited in between a plurality of structures disposed over a surface of the substrate. The structures have a high aspect ratio greater than 5:1, such as greater than 10:1. The epitaxial deposition includes deposition of the film at a temperature of about 400° C. to about 1200° C., such as about 800° C. to about 1000° C., such as about 950° C. The film is deposited using a precursor gas. The precursor gas may include a silicon precursor, such as trichlorosilane (SiHCl₃) and dichlorosilane (DCS). The epitaxial deposition is conducted at a pressure of about 700 Torr to about 800 Torr, such as about 760 Torr. The epitaxial deposition is conducted for a time of about 15 second to about 45 second, such as about 30 seconds, or about 100 seconds to about 5000 seconds, such as about 500 seconds to about 1000 seconds, such as about 700 seconds.

The atmospheric pressure (ATM) low temperature epitaxial deposition increases the dopant diffusion control, e.g., reduces the dopant diffusion into the deposited film. Pre-cleaning the substrate prior to the low temperature epitaxial deposition removes the native oxide layer is from the substrate. Removal of the native oxide layer, thus, enables the low temperature epitaxial deposition. In addition, the low temperature atmospheric epitaxial deposition increases throughput in a manufacturing environment compared to low pressure epitaxial deposition. The throughput is increased via an increase in epitaxial growth during the epitaxial deposition. Further, the low temperature epitaxial deposition enables selective epitaxial deposition.

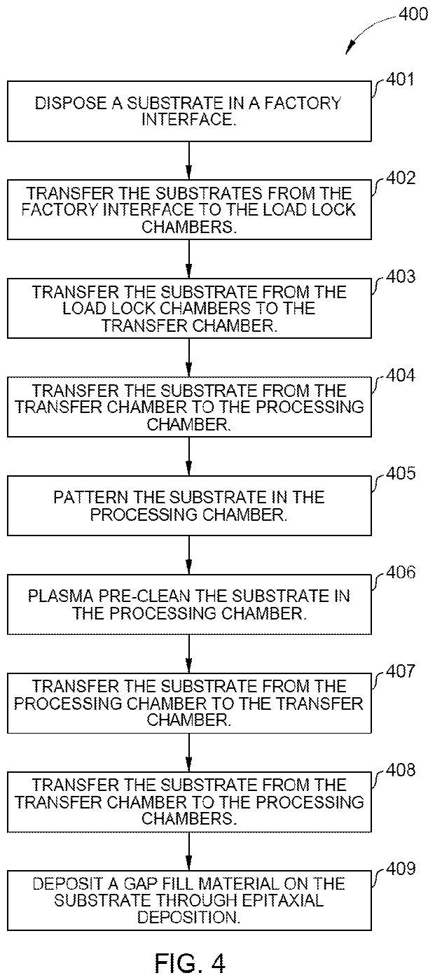

FIG. 4 is a method 400 for low temperature gap filling using epitaxial deposition. At operation 301, a substrate is disposed in the factory interface 102. The factory interface 102 includes a docking station 132 and factory interface robots 134 to facilitate transfer of substrates. The docking station 132 is adapted to accept one or more front opening unified pods (FOUPs) 136.

At operations 402, the substrates are transferred from the factory interface 102 to the load lock chambers 104, 106. In some examples, each factory interface robot 134 generally includes a blade 138 disposed on one end of a respective factory interface robot 134 adapted to transfer the substrates from the factory interface 102 to the load lock chambers 104, 106. The load lock chambers 104, 106 have respective ports 140, 142 coupled to the factory interface 102 and respective ports 144, 146 coupled to a transfer chamber 108.

At operation 403, the substrate is transferred from the load lock chambers 104, 106 to the transfer chamber 108. The transfer chamber 108 has respective ports 148, 150 coupled to the holding chambers 116, 118 and respective ports 152, 154 coupled to processing chambers 120, 122.

At operation 404, the substrate is transferred from the transfer chamber 108 to the processing chambers 120, 122. The transfer chamber 108 has a pressure of about 700 Torr to about 800 Torr, such as about 760 Torr.

At operation 405, a substrate is patterned in the processing chamber 120, 122. The substrate is patterned to form high aspect ratio structures, such as structures with an aspect ratio greater than about 5:1, such as greater than about 10:1. In some embodiments, the substrate may be patterned using a lithography process to form a plurality of structures. In other embodiments, the substrate may be patterned using a deposition process to form a plurality of structures. The deposition process may include atomic layer deposition (ALD), chemical vapor deposition (CVD), or physical vapor deposition (PVD).

At operation 406, the substrate is plasma pre-cleaned in the processing chambers 120, 122. In some embodiments, the substrate is transferred to the other of the processing chamber 120, 122. In other embodiments, the substrate is plasma pre-cleaned in the same processing chamber 120, 122 as the patterning. The pre-clean process includes removing a native-oxide from the substrate. The plasma pre-clean is conducted at a temperature of about 100° C. to about 300° C., such as about 150° C. to about 250° C., such as about 200° C. The plasma pre-clean is conducted at a pressure of about 1 Torr to about 5 Torr, such as about 3 Torr. The plasma pre-clean is conducted for a time of about 15 second to about 45 second, such as about 30 seconds.

At operation 407, the substrate is transferred from the processing chambers 120, 122 to the transfer chamber 110. The substrate is transferred to the transfer chamber 110 via the holding chambers 116, 118. The transfer chamber 110 has respective ports 156, 158 coupled to the holding chambers 116, 118 and respective ports 160, 162, 164, 166 coupled to processing chambers 124, 126, 128, 130.

At operation 408, the substrate is transferred from the transfer chamber to the processing chambers 124, 126, 128, 130. The transfer chamber 108 has a pressure of about 700 Torr to about 800 Torr, such as about 760 Torr.

At operation 409, a gap fill material is deposited on the substrate through epitaxial deposition. The gap fill material is deposited in between the structures formed on the substrate. The epitaxial deposition includes deposition of the gap fill material at a temperature of about 400° C. to about 1200° C., such as about 800° C. to about 1000° C., such as about 950° C. The gap fill is deposited using a precursor gas. The precursor gas includes a silicon precursor, such as SiHCl₃ and DCS. The flow rate of the precursor gas may depend on the precursor gas being used. For example, a flow rate for SiHCl₃ a may be about 10 standard liter per minute (slm) to about 20 slm, such as about 15 slm. In another example, a flow rate for DCS may be about 400 standard cubic centimeters per minute (sccm) to about 1000 sccm. The epitaxial deposition is conducted at a pressure of about 700 Torr to about 800 Torr, such as about 760 Torr. The epitaxial deposition is conducted for a time of about 100 seconds to about 5000 seconds, such as about 500 seconds to about 1000 seconds, such as about 700 seconds.

The atmospheric pressure (ATM) low temperature epitaxial deposition increases throughput in a manufacturing environment compared to low pressure epitaxial deposition. The throughput is increased via an increase in epitaxial growth during the epitaxial deposition. Further, the low temperature epitaxial deposition enables selective epitaxial deposition, e.g., the orientation of epitaxial deposition of the gap fill material can be selected to form a void free substrate. The low temperature epitaxial deposition enables the selective epitaxial deposition along the gaps formed in between the structures while reducing deposition across the structures. The reduction in the deposition across the structures reduces the likelihood that the gap fill material prematurely closes the gap in between the structures, enabling more gap fill material to be deposited in the gaps between the structures.

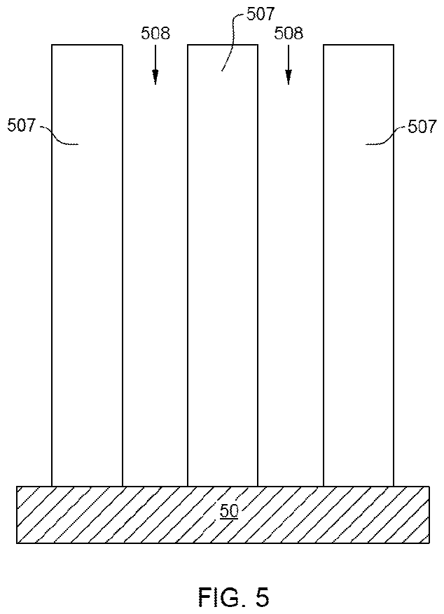

FIG. 5 is a cross-sectional view of the substrate 50 having structures 507 disposed thereon. The structures 507 define openings 508. The openings 508 are about 1.0 μm and about 1.3 μm wide, have a high aspect ratio (e.g., greater than about 5:1, such as greater than about 10:1), and a pitch between adjacent openings 508 of between about 50 nm and about 180 nm. During methods 300 and 400, the material may be deposited over the structures 507 and in the openings 508 to fill the area in between the structures 507. The structures 507 may include refractory metals, such as tungsten (W), molybdenum (Mo), tantalum (Ta), titanium (Ti), hafnium (Hf), vanadium (V), chromium (Cr), manganese (Mn), ruthenium (Ru), alloys thereof, silicide compounds thereof, nitride compounds thereof, or combinations thereof. In other examples, the structure 507 may be other metals, such as copper (Cu), nickel (Ni), cobalt (Co), iron (Fe), aluminum (AI), palladium (Pd), gold (Au), silver (Au), platinum (Pt), alloys thereof, nitride compounds thereof, or combinations thereof. In other embodiments, the structures may be silicon or silicon germanium (SiGe).

In summary, the methods described above include low temperature epitaxial deposition processes. The low temperature atmospheric epitaxial deposition includes a deposition temperature of about 400° C. to about 1200° C. and a deposition time of about 15 seconds to about 45 seconds. The low temperature atmospheric epitaxial deposition overcomes the drawbacks of low pressure deposition by increasing throughput in a manufacturing environment. Further, the low temperature epitaxial deposition enables more efficient gap filling, selective epitaxial deposition, and increased dopant diffusion control.

While the foregoing is directed to embodiments of the present disclosure, other and further embodiments of the disclosure may be devised without departing from the basic scope thereof, and the scope thereof is determined by the claims that follow.

We claim:

1. A method of epitaxial deposition, comprising:
plasma pre-cleaning a substrate having openings with an aspect ratio of greater than 5:1, wherein the plasma pre-cleaning is performed at pre-clean pressure of less than 5 Torr; and
after the plasma pre-cleaning, depositing a material in the openings using epitaxial deposition at a deposition pressure of about 700 Torr to about 800 Torr.

2. The method of claim 1, further comprising:
disposing the substrate in a factory interface; and
transferring the substrate from the factory interface to the processing chamber.

3. The method of claim 1, wherein:
the plasma pre-cleaning occurs in a first processing chamber of a substrate processing system; and
the epitaxial deposition occurs in a second processing chamber of the substrate processing system.

4. The method of claim 3, further comprising:
transferring the substrate from the first processing chamber to the second processing chamber.

5. The method of claim 4, wherein a transfer chamber between the first processing chamber and the second processing chamber has a pressure of about 700 Torr to about 800 Torr.

6. The method of claim 1, wherein:
the plasma pre-cleaning comprises a pre-clean temperature of about 100° C. to about 300° C.;
the deposition of the material comprises a deposition temperature of about 400° C. to about 1200° C.; and
the deposition of the material comprises a deposition time of about 100 seconds to about 5000 seconds.

7. A method of gap filling using epitaxial deposition, comprising:
patterning a substrate with openings having an aspect ratio of 5:1;
plasma pre-cleaning the substrate, wherein the plasma pre-cleaning is performed at a pre-clean pressure of about 1 Torr to about 5 Torr; and
after the plasma pre-cleaning, depositing a gap fill material in the openings using epitaxial deposition at a deposition pressure of about 700 Torr to about 800 Torr.

8. The method of claim 7, further comprising:
disposing the substrate in a factory interface; and
transferring the substrate from the factory interface to the processing chamber.

9. The method of claim 7, wherein:
the patterning occurs in a first processing chamber of a substrate processing system;
the plasma pre-cleaning occurs in a second processing chamber of the substrate processing system; and
the epitaxial deposition occurs in a third processing chamber of the substrate processing system.

10. The method of claim 9, further comprising:
transferring the substrate from the first processing chamber to the second processing chamber; and
transferring the substrate from the second processing chamber to the third processing chamber.

11. The method of claim 10, wherein a transfer chamber between the first processing chamber, the second processing chamber, and the third processing chamber has a pressure of about 700 Torr to about 800 Torr.

12. The method of claim 7, wherein:
the plasma pre-clean comprises a pre-cleaning temperature of about 100° C. to about 300° C.;
the deposition of the material comprises a deposition temperature of about 400° C. to about 1200° C.; and
the deposition of the material comprises a deposition time of about 100 seconds to about 5000 seconds.

13. A processing system, comprising:
one or more processing chambers; and
a system controller configured to cause the processing system to perform, in the one or more processing chambers:
plasma pre-cleaning a substrate having openings with an aspect ratio of greater than 5:1, wherein the plasma pre-cleaning is performed at a pre-clean pressure of about 1 Torr to about 5 Torr; and
after the plasma pre-cleaning, depositing a material in between the structures using epitaxial deposition at a deposition pressure of about 700 Torr to about 800 Torr.

14. The processing system of claim 13, wherein the plasma pre-clean comprises a pre-clean temperature of about 100° C. to about 300° C.

15. The processing system of claim 13, further comprising transferring the substrate.

16. The processing system of claim 13, wherein:
the plasma pre-cleaning occurs in a first processing chamber of a substrate processing system; and
the epitaxial deposition occurs in a second processing chamber of the substrate processing system.

17. The processing system of claim 16, further comprising:
transferring the substrate from the first processing chamber to the second processing chamber.

18. The processing system of claim 17, wherein a transfer chamber between the first processing chamber and the second processing chamber has a pressure of about 700 Torr to about 800 Torr.

19. The processing system of claim 13, further comprising:
patterning a substrate in a processing chamber prior to the plasma pre-cleaning.

20. The processing system of claim 19, further comprising:
the patterning occurs in a first processing chamber;
transferring the substrate from the first processing chamber to the second processing chamber;
the plasma pre-cleaning occurs in a second processing chamber;
transferring the substrate from the second processing chamber to a third processing chamber; and
the epitaxial deposition occurs in a third processing chamber.
